(19) United States
(12) Patent Application Publication
(10) Pub. No.: US 2024/0119200 A1
(43) Pub. Date: Apr. 11, 2024

(54) METHOD AND SYSTEM OF BUILDING CHARACTERISTIC MODEL BASED ON DATA ANNEALING PROCESS

(71) Applicant: MEDIATEK INC., Hsin-Chu (TW)

(72) Inventors: Yu-Jen Chen, Hsinchu City (TW); Chien-Chih Wang, Hsinchu City (TW); Wen-Wen Hsieh, Hsinchu City (TW); Ying-Yi Teng, Hsinchu City (TW)

(73) Assignee: MEDIATEK INC., Hsin-Chu (TW)

(21) Appl. No.: 18/375,999

(22) Filed: Oct. 3, 2023

Related U.S. Application Data
(60) Provisional application No. 63/378,555, filed on Oct. 6, 2022.

(51) Int. Cl. G06F 30/27

(52) U.S. Cl. CPC G06F 30/27

(57) ABSTRACT

A method of building a characteristic model includes: acquiring raw electrical data from a measurement system outside one or more processing units; acquiring operational state-related data from an information collector inside the one or more processing units; performing a data annealing process on the raw electrical data and the operational state-related data to obtain and purified electrical data and purified operational state-related data; and performing a machine learning (ML)-based process to build the characteristic model based on the purified electrical data and the purified operational state-related data.

### CROSS REFERENCE TO RELATED APPLICATIONS

This application claims the benefit of U.S. Provisional Application No. 63/378,555, filed on Oct. 6, 2022. The content of the application is incorporated herein by reference.

### BACKGROUND

The present invention relates to machine learning, and more particularly, to a method and a modeling system of building a characteristic model for xPU and its associated system units by utilizing a data annealing process to purify training data.

In the realm of high-performance computing, a precise and real-time power estimation model for a computing processor (xPU) and its associated system unit(s) has become increasingly important. In general, the associated unit(s), including memory subsystem, snooping, and interconnection, can cluster xPUs, all of their power estimations can be modeled with xPU operation behaviors. However, existing techniques face numerous challenges in building an accurate and real-time power estimation model for the xPU. Methodologies in the prior art for power estimation modeling typically rely on additional circuits, extensive data processing, and intricate modeling methods. In addition, a critical drawback of these methodologies is the stability and the reliability of the models. Models built by methodologies in the prior art are usually vulnerable and unstable under various physical effects and environmental factors, which become a severe issue for high-performance computing systems that need to operate under different environments and conditions.

### SUMMARY

With this in mind, it is one object of the present invention to provide a methodology of building a characteristic model for an xPU based on data annealing process and a machine learning-based process. The data annealing process is utilized to provide purified data that is essential, accurately reflecting characteristics of the xPU. Training with the purified data yields a robust characteristic model, enabling the estimation of power and performance of across all variants of the xPU, in both pre-silicon and post-silicon stages. The methodology of the present invention can overcome the limitations of methodologies in the prior art and maintain model stability and reliability under a variety of physical effects and environmental factors.

According to one embodiment, a method of building a characteristic model is provided. The method comprises: acquiring raw electrical data from a measurement system outside one or more processing units; acquiring operational state-related data from an information collector inside the one or more processing units; performing a data annealing process on the raw electrical data and the operational state-related data to obtain purified electrical data and purified operational state-related data; and performing a machine learning (ML)-based process to build the characteristic model based on the purified electrical data and the purified operational state-related data.

According to one embodiment, a modeling system of building a characteristic model is provided. The modeling system comprising: a data annealing process and a machine learning (ML)-based process. The data annealing process is configured to purify raw electrical data from a measurement system outside one or more processing units and operational state-related data from an information collector inside the one or more processing units, thereby to obtain purified electrical data and purified operational state-related data. The ML-based process is configured to build the characteristic model based on the purified electrical data and the purified operational state-related data.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates an overview of a modeling system according to one embodiment of the present invention.

FIG. 2A illustrates time alignment on raw electrical data and operational state-related data according to one embodiment of the present invention.

FIG. 2B illustrates time alignment on raw electrical data and operational state-related data according to another embodiment of the present invention.

FIG. 2C illustrates how filtering processes apply to samples of raw electrical data according to another embodiment of the present invention.

FIG. 3 illustrates a flow chart regarding how to select features from the operational state-related data based on a stepwise regression method according to one embodiment of the present invention.

FIG. 4 illustrates a flow chart of a method of building a characteristic model according to one embodiment of the present invention.

### DETAILED DESCRIPTION

In the following description, numerous specific details are set forth in order to provide a thorough understanding of the present embodiments. It will be apparent, however, to one having ordinary skill in the art that the specific detail need not be employed to practice the present embodiments. In other instances, well-known materials or methods have not been described in detail in order to avoid obscuring the present embodiments.

Reference throughout this specification to “one embodiment” or “an embodiment” means that a particular feature, structure or characteristic described in connection with the embodiment or example is included in at least one embodiment of the present embodiments. Thus, appearances of the phrases “in one embodiment” or “in an embodiment” in various places throughout this specification are not necessarily all referring to the same embodiment. Furthermore, the particular features, structures or characteristics may be combined in any suitable combinations and/or sub-combinations in one or more embodiments.

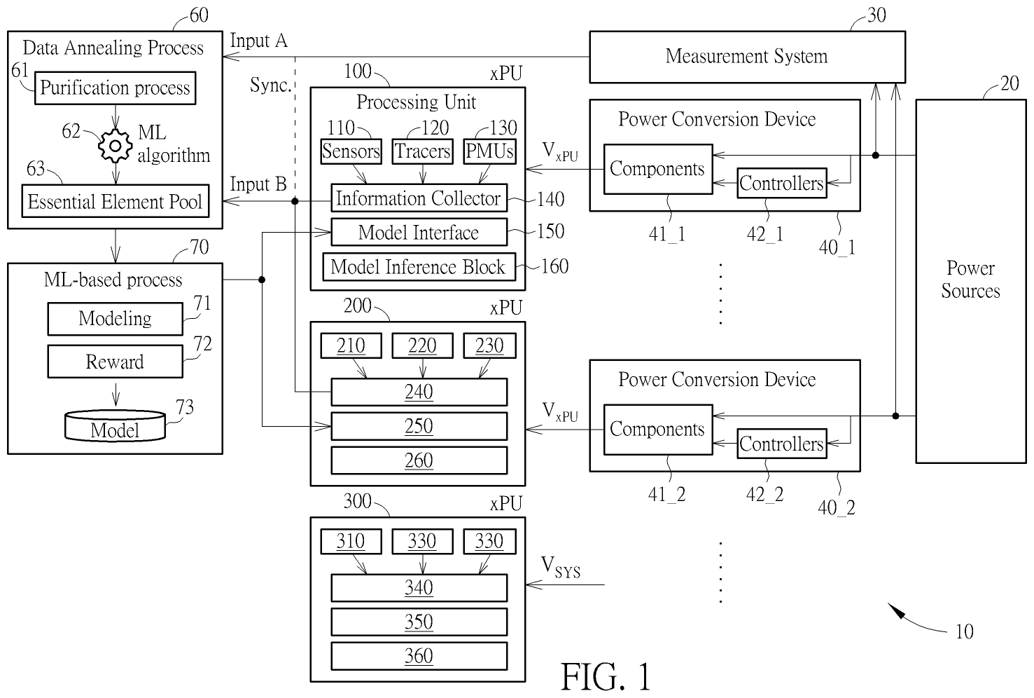

Please refer to FIG. 1, which illustrates an overview of a modeling system according to one embodiment of the present invention. As depicted, a modeling system 10 is configured to collect data from one or more processing units 100 and 200 (which can be any types of processing units (referred to as xPU)), and at least one associated system unit 300 interconnected to the one or more processing units 100 and 200. The modeling system 10 is configured to build one or more characteristic models applicable to all circuit variants of the one or more processing units 100 and 200, as well as the associated system unit 300. Specifically, the one or more characteristic models can be applicable to the processing unit and the associated system unit, separately or in combination. According to various embodiments of the present invention, the one or more processing units 100 and 200 could be central processing units (CPUs), graphic processing units (GPUs) or CPU clusters. According to various embodiments of the present invention, the associated system unit 300 can be a memory system, a control unit, external interface or any other subsystems/units/circuits that can be integrated with the one or more processing units 100 and 200 to form a system (e.g., computer system, embedded system, or high performance computing system)

The modeling system 10 includes a measurement system 30, a data annealing process 60 and a machine learning (ML)-based process 70. The measurement system 30 is configured to collect raw electrical data from the outside of the one or more processing units 100 and 200. The data annealing process 60 is configured to purify the raw electrical data, as well as operational state-related data obtained from internal information inside the processing units 100 and 200, and the associated system unit 300. The data annealing process 60 yields purified electrical data (which serves as observed target variables or ground truth labels for model training), as well as purified operational state-related data (which serves as features for model training). Subsequently, the ML-based process 70 is configured to train the characteristic model based on the observed target variables and the features.

As depicted, one or more power sources 20 are configured to supply electrical energy to the one or more processing units 100 and 200 and the associated system unit 300 in the form of voltage and current. According to various embodiments of the present invention, the one or more power source 20 may be power rails or energy banks. In one embodiment, the power rails may be voltage buses at levels such as 1.8V, 3.3V, 5V, 12V, 24V, 48V, or other voltage levels. In one embodiment, the energy banks may be capacitors, batteries, or any types of energy storage units. The voltage supplied by the one or more power sources 20 will be provided to a plurality of power conversion devices 40_1, 40_2 . . . to produce stable and regulated voltages V_{xPU} and V_{SYS} for the one or more processing units 100 and 200, and the associated system unit 300. According to various embodiments of the present invention, the power conversion devices 40_1, 40_2 . . . may be voltage regulators, switching power converters, low-dropout regulators, integrated voltage regulators, or any kind of power conversion circuit with power management integrated circuits (PMICs). In one embodiment, each of power conversion devices 40_1, 40_2 . . . may comprise electrical components (41_1, 41_2 . . . ) as well and one or more controllers (42_1, 42_2 . . . ).

A measurement system 30 is configured to provide raw electrical data by measuring voltage and current associated with power supplied by the one or more power sources 20 to the power conversion devices 40_1, 40_2 . . . . That is, the raw electrical data may be regarded as an approximate indication of power consumption of the one or more processing units 100 and 200, and the associated system unit 300. According to various embodiments of the present invention, the measurement system 30 could be a data acquisition system (DAQ), a data recorder, or an oscilloscope. The measurement system 30 measures voltage and current associated with power supplied by the one or more power sources 20 to provide the raw electrical data under different scenarios. According to various embodiments of the present invention, these different scenarios may include execution of different tasks or software applications, and operation under different workloads. After measurement, the measurement system 30 will deliver the raw electrical data (labeled as Input A in FIG. 1) to a data annealing process 60 within the modeling system 10 for subsequent model training.

On the other hand, each of the one or more processing units 100 and 200 comprises one or more sensors (110 and 210), one or more tracers (120 and 220) and one or more performance monitoring units (PMUs) (130 and 230) that are used to provide internal information of processing units (100 and 200), indicating operational state of the processing units 100 and 200. In addition, the associated system unit 300 comprises one or more sensors 310, one or more tracers 320 and one or more PMUs 330 that are used to provide internal information of the associated system unit 300, indicating operational state of the associated system unit 300.

The internal information under different scenarios is recorded by an information collector (140, 240 and 340). According to various embodiments of the present invention, these different scenarios may include execution of different tasks or software applications, and operation under different workloads. Accordingly, the information collector (140 and 240) provides the recorded internal information, as operational state-related data (labeled as Input B in FIG. 1), to the data annealing process 60. According to various embodiments, the operational state-related data may include attributes of the one or more processing units 100 and 200, and the associated system unit 300, such as, voltage, temperature, clock frequency, number of active cores, active cycle, cache usage, memory system bandwidth utilization and instruction mix (which refers to a distribution of different types of instructions (e.g., integer operations, floating-point operations, memory instructions or vector instructions) in a particular program or workload).

While the measurement system 30 is acquiring the raw electrical data, the information collector (140, 240 and 340) is simultaneously recording the internal information, such that the raw electrical data and the operational state-related data can be accurately aligned in terms of timing. Specifically, the raw electrical data and the operational state-related data can be aligned based on various synchronization indictors, such as timestamps.

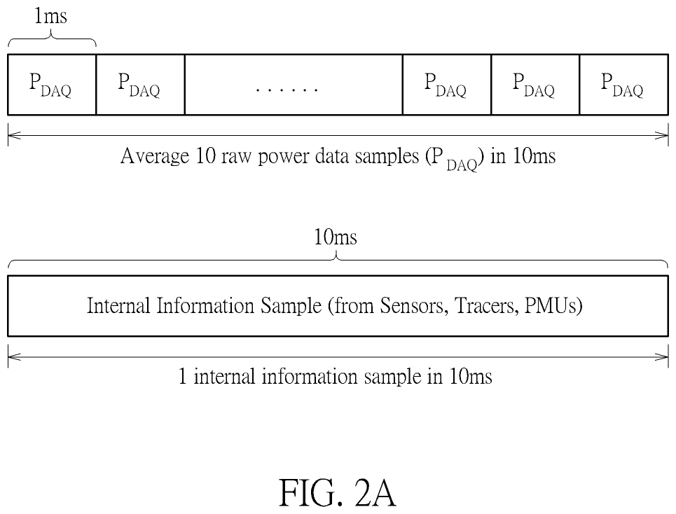

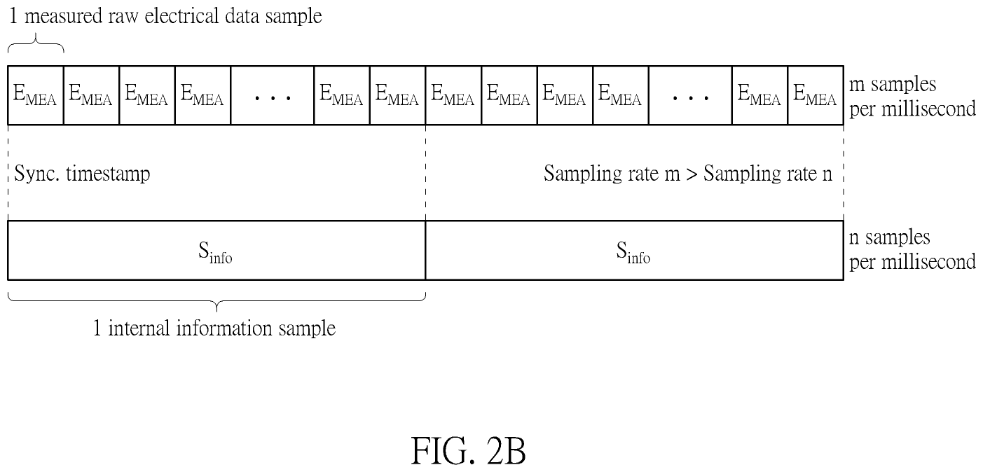

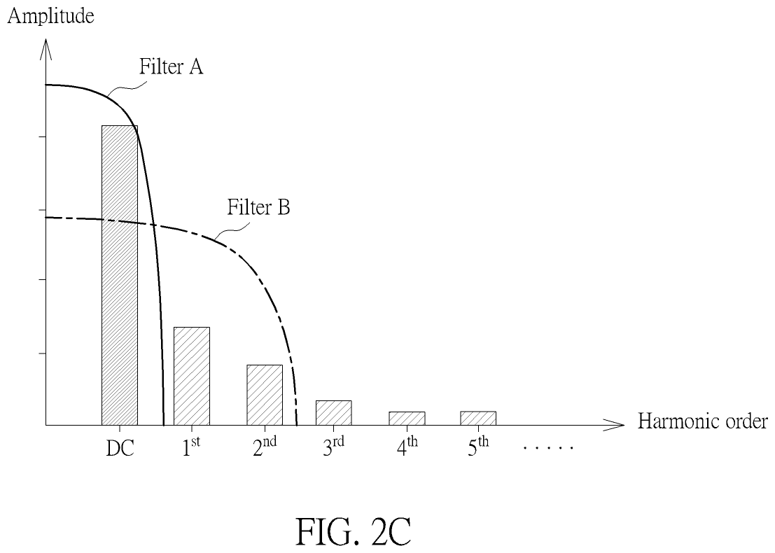

Moreover, before the raw electrical data and the operational state-related data are provided to the data annealing process 60, a synchronization process will be performed to ensure that the raw electrical data and the operational state-related data align temporally. Please refer to FIG. 2A for further understandings. As depicted in FIG. 2A, the synchronization process is configured to sample measurement of measurement system 30 (which measures electrical voltage and current outputted by the power source 20 to generate the raw electrical data) at a relatively high sampling rate of m samples per millisecond (e.g., sampling rate of 1/(1 ms) can obtain 10 samples of raw electrical data during a 10 ms synchronization period). On the other hand, internal information recorded by the information collectors 140, 240 and 340 is sampled at a relatively low sampling rate of n samples per millisecond to obtain n sample of the internal information during the synchronization period (e.g., sampling rate of 1/(10 ms) can obtain n sample of the internal information during an 10 ms synchronization period).

FIG. 2B illustrates time alignment on raw electrical data and operational state-related data according to another embodiment of the present invention. In this embodiment, the sampling rate for the raw electrical data (e.g. E_{MEA}) is m per millisecond, which means m samples of the raw electrical data can be obtained during 1 millisecond. In addition, the sampling rate for the internal information (e.g. S_{info}) is n per millisecond, which means m samples of the raw electrical data can be obtained during 1 millisecond. Since the sampling rate m for the raw electrical data E_{MEA} is greater than the sampling rate n for the internal information S_{info}, there are more samples of the raw electrical data E_{MEA} than the internal information S_{info} during a given time period. In addition, the samples of the raw electrical data E_{MEA} and the internal information S_{info} can be synchronized through timestamps.

The synchronization process is configured to serve filtering results of m samples of raw electrical data as raw measured electrical data E_{MEA} to provide to the data annealing process 60. Also, the synchronization process is configured to serve n samples of the internal information as the operational state-related data to provide to the data annealing process 60. As such, the raw electrical data and the operational state-related data can temporally align during each synchronization period. Moreover, filtering samples of the raw electrical data E_{MEA} also mitigates the influence of noise and measurement errors. Please note that, sampling periods mentioned above (e.g., 10 ms and 1 ms) are just for illustrative purposes rather than limitations of the present invention. According to various embodiments of the present invention, one or more of filtering processes may be applied to samples of raw electrical data E_{MEA}. For example, a low-pass filtering process can be firstly applied to the samples of the raw electrical data. If not sufficient, one or more specific filtering processes can be used to further attenuate specific orders of harmonic components in the samples of the raw electrical data E_{MEA}. Please refer to FIG. 2C for further understanding. As illustrated, one filtering process (i.e., Filter A) can be used to attenuate harmonic components except DC component in the samples of the raw electrical data, while another filtering process (i.e., Filter B) can be used to attenuate higher-order harmonic components except lower-order harmonic components in the samples of the raw electrical data E_{MEA}.

Please refer to FIG. 1 again. The data annealing process 60 (which may be executed by a specific hardware platform) is configured to purify the raw electrical data and the operational state-related data, thereby removing any unwanted noise and outliers, and accordingly producing refined data sets for subsequent model training. The data annealing process 60 includes a purification process 61, a machine-learning (ML) algorithm 62, and an essential element pool 63. The purification process 61 is configured to purify the raw electrical data E_{MEA}, which indicates electrical signal (e.g., power) provided from the power sources 20 to one of the power conversion devices (40_1, 40_2 . . . ). First, the purification process 61 is configured to calculate processing unit electrical data E_{xPU} based on the raw electrical data E_{MEA} and an electrical conversion efficiency η_{PMIC}, where “E_{MEA}*η_{PMIC}=E_{xPU}”. Specifically, the electrical conversion efficiency η_{PMIC} may be an electrical signal conversion efficiency that one or more of the power conversion devices (40_1, 40_2 . . . ) correspond to. For example, the conversion efficiency η_{PMIC} may indicate a ratio of an output power to an input power, a ratio of an output current to an input current, and/or a ratio of an output voltage to an input voltage.

Accordingly, the purification process 61 calculate ground true electrical data E_{xPU_gt} based on the processing unit electrical data E_{xPU} and an electrical leakage data E_{lkg}, where “E_{xPU}−E_{lkg}=E_{xPU_gt}”. In one embodiment, the leakage electrical data E_{lkg} can be evaluated by the sensor data collected from the sensors 110, 210 and 310 in the processing units and associated system unit 100, 200 and 300. For example, the leakage electrical data E_{lkg} could be a leakage current and/or a leakage power that is evaluated by the internal sensors in the processing units and associated system unit 100, 200 and 300.

The ground true electrical data E_{xPU_gt} is the purified electrical data generated by the purification process 61, which can serve as a target variable or a ground truth label for modeling training. In view of the above, the purification process 61 is configured to mitigate the impact of physical effects and environmental factors, on the reflection of electrical characteristics of the one or more processor units 100 and 200, and the associated system unit 300 such as extra power and voltage fluctuations caused by electrical, thermal, pressure, temperature or other factors. Please note that, one form of the raw measured electrical data E MEA can be raw electrical power. According to various embodiments, the raw measured electrical data E MEA may include much more information, thereby to further reflect other types of electrical characteristics (of the processor units 100 and 200, and the associated system unit 300) rather than just power. In this regards, the purification process 61 is configured to calculate ground true electrical data by mitigating the impact of physical effects and environmental factors, on the reflection of electrical characteristics of the one or more processor units 100 and 200, and the associated system unit 300.

The ML algorithm 62 is executed to purify the operational state-related data to select essential features from a variety of attributes of the one or more processing units 100 and 200, and the associated system unit 300. The operational state-related data provided by the information collector (140, 240 and 340) may comprise attributes such as, sensor data from sensors (110, 210 and 310), xPU signal data from tracers (120, 220 and 320) and PMU counter data from PMUs (130, 230 and 330), which may include voltage, temperature, clock frequency, number of active cores, active cycle, cache usage, memory system bandwidth utilization and instruction mix. To select features that are most relevant to the target variable (i.e., the true power (or true electrical data) of the one or more processing units 100 and 200, and the associated system unit 300) for model training, the ML algorithm 62 is employed to perform feature selection from variety of attributes included in the operational state-related data. As such, those features that have significant impacts on and are highly correlated with the target variable (i.e., true power or true electrical data of the one or more processing units 100 and 200, and the associated system unit 300) can be retained.

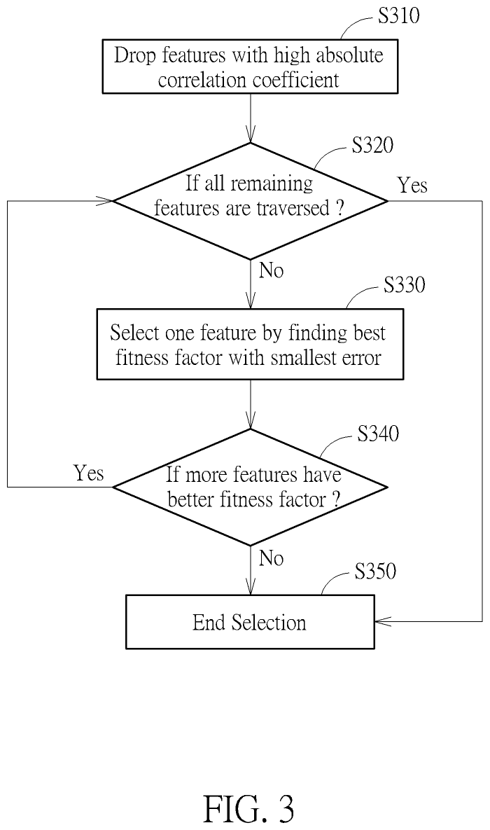

In one embodiment, essential features are selected based on a stepwise regression method. Please refer to FIG. 3, which illustrates a flow chart regarding how to select features based on a stepwise regression method according to one embodiment of the present invention. The flow comprises following steps:
S310: Drop features with high absolute correlation coefficient;
S320: If all remaining features are traversed;
S330: Select one feature by finding best fitness factor with smallest error;
S340: If more features have better fitness factor; and
S350: End Selection.

At step S310, features with high correlation factors to other features will be dropped. In one embodiment, features with correlation factors greater than a predetermined threshold (e.g., 10) are dropped. For example, typically, a feature with variance inflation factor (VIF) greater than 10 indicates that this feature is highly correlated with other features, which may have detrimental effect on model training and lead to a vulnerable and unstable model. In view of this, features with high correlation factors are dropped, thereby to retain features with strong orthogonality. At step S320, it is determined if all remaining features are traversed. If not, the flow proceeds to step S330; otherwise, the flow proceeds to step S350. At step S330, one feature is selected by finding the best coefficient of fitness for fitting the purified electrical data with the smallest error from all the features. Generally, the residual sum of squares, RSS, is a measure of discrepancy between data and a model (i.e., observed target variables and their corresponding predicted target variables from the trained model). A smaller RSS indicates a lower prediction error and better prediction ability of the model. On the other hand, the coefficient of determination R² is a measure of goodness-of-fit, where a higher R² indicates a better fit of the model to the data. Thus, when one feature exhibits the best (i.e., highest) R² with the smallest RSS, it indicates that this feature holds a significant impact on and is most relevant to the target variable (i.e., the ground true power or ground true electrical data of the one or more processor units 100 and 200, and the associated system unit 300). In view of this, in one embodiment of the present invention, R² and RSS may be used to evaluate whether or not one feature has the best coefficient of fitness for fitting the purified electrical data with the smallest error. At step S340, it is determined if there are more features with better coefficient of fitness (e.g., R²) for fitting the purified electrical data. If not, the flow returns to step S320, which leads to selecting another feature; other, the flow proceeds to step S350, ending selection.

In short, the ML algorithm 62 first selects a plurality of features from all attributes of the one or more processing units 100 and 200, and the associated system unit 300 for feature selection. Then, the ML algorithm 62 selects a plurality of first selected features from the features by dropping those features having high correlation factors to retain features with strong orthogonality. Consequently, the ML algorithm 62 selects the essential features from the first selected features, wherein the coefficients of determination R² that the selected essential features correspond to are higher than the coefficients of determination R² that others in the first selected features correspond to, and the residual sums of squares RSS that the selected essential features correspond to are smaller than the residual sums of squares RSS that others in the first selected features correspond to.

In one embodiment, before using the stepwise regression method of FIG. 3 to select the essential features, the ML algorithm 62 is configured to calculate correlation coefficient (e.g., Pearson correlation coefficient) with respect to each attribute of the one or more processing units 100 and 200 included in the operational state-related data and the ground true power or ground true electrical data of the one or more processing units 100 and 200, and the associated system unit 300, so as to exclude specific attributes from being selected as features. For example, attributes having correlation coefficient greater than a predetermined threshold will be retained for being selected by the stepwise regression method of FIG. 3. Conversely, attributes having correlation coefficient lower than the predetermined threshold will be dropped and not for feature selection. In one embodiment, the selected essential feature may include computing intensive attributes (e.g., CPU usage, processor load, number of running threads) of the one or more processing units 100 and 200, and the associated system unit 300, as well as memory intensive attributes (e.g., memory utilization, memory bandwidth utilization, cache usage, memory footprint) of the one or more processing units 100 and 200, and the associated system unit 300.

After the essential features are selected, the ML algorithm 62 therefore obtains the purified operational state-related data. The purified electrical data and the purified operational related-state data will be stored in the essential element pool 63, and then provided to the ML-based process as apart of data sets (e.g., features and observed target variable/ground truth labels) for model training.

The ML-based process 70 (which may be executed by a specific hardware/software platform) is configured to train a characteristic model. The ML-based process 70 includes a modeling module 71 and a reward module 72. The modeling module 71 is configured to train the characteristic model based on the data sets including the purified electrical data and the purified operational state-related data provided by the data annealing process 60. According to various embodiments of the present invention, the modeling module 71 can train the characteristic model based on at least one of linear regression method, regular linear regression method, polynomial regression method, decision trees method, random forest regression method, neural net method, graph neural networks method, convolutional neural networks method, reinforcement learning method, and other ML training methods. The reward module 72 is configured to assess predictions of a model (agent). Specifically, the reward module 72 is configured to assess the predictions of the model (agent) according to some objectives or standards and provide corresponding reward signals to the modeling model 71 based on this assessment. Then, these reward signals can be used to guide the modeling module 71 to optimize model training. After trained, a built characteristic model 73 can be deployed on the one or more processing units 100 and 200, and the associated system unit 300 through model interfaces 150, 250 and 350, respectively.

The one or more processing unit 100 and 200 and the associated system unit 300 could further comprise model inference blocks 160, 260 and 360, respectively. The model inference blocks 160, 260 and 360 are configured to store the deployed built characteristic model 73 and performing model inference through hardware or software, thereby to achieve accurate and real-time power estimation or other types of electrical characteristics estimation, such as capacitance, admittance, impedance and current estimation.

Moreover, through the model interfaces 150, 250 and 350, the ML-based process 70 is further allowed to perform runtime training on the built characteristic model 73 that has been deployed on the one or more processing circuits 100 and 200, and the associated system unit 300, thereby to perform adjustment or optimization on the built characteristic model 73 that has been deployed.

Typically, the characteristic model 73 can be regarded as a capacitance estimation model for all variants of the one or more processing units 100 and 200, and the associated system unit 300. However, the characteristic model 73 can be converted to different models for estimating different characteristics of the one or more processing units 100 and 200, and the associated system unit 300. In one embodiment, the built characteristic model 73 can be further converted into an admittance/impedance estimation model for all variants of the one or more processing units 100 and 200, and the associated system unit 300 based on frequency data dumped by the information collector 140, 240, and 340. In one embodiment, the built characteristic model 73 can be converted into a power estimation model for all variants of the one or more processing units 100 and 200 based on voltage data and frequency data dumped by the information collector 140 240, and 340.

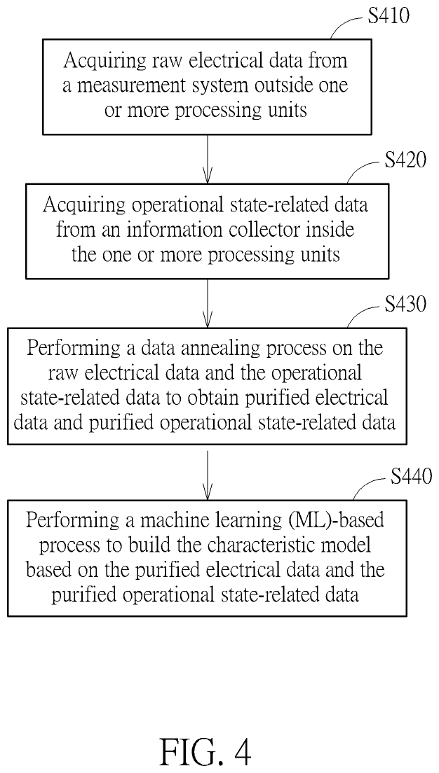

Please refer to FIG. 4, which illustrates a flow chart of building a characteristic model according to one embodiment of the present invention. The flow comprises following steps:
S410: acquiring raw electrical data from a measurement system outside one or more processing units;
S420: acquiring operational state-related data from an information collector inside the one or more processing units;
S430: performing a data annealing process on the raw electrical data and the operational state-related data to obtain the purified electrical data and purified operational state-related data; and
S440: performing a machine learning (ML)-based process to build the characteristic model based on the purified electrical data and the purified operational state-related data.

Since the principles and specific details of the foregoing steps have been explained in detail through the above embodiments, further descriptions will not be repeated here. It should be noted that the above flow can be enhanced by adding other extra steps or making appropriate modifications and adjustments, to improve the performance of the built characteristic model and the efficiency of model training.

Embodiments in accordance with the present embodiments can be implemented as an apparatus, method, or computer program product. Accordingly, the present embodiments may take the form of an entirely hardware embodiment, an entirely software embodiment, or an embodiment combining software and hardware aspects that can all generally be referred to herein as a “module” or “system.” Furthermore, the present embodiments may take the form of a computer program product embodied in any tangible medium of expression having computer-usable program code embodied in the medium. In terms of hardware, the present invention can be accomplished by applying any of the following technologies or related combinations: an individual operation logic with logic gates capable of performing logic functions according to data signals, and an application specific integrated circuit (ASIC), a programmable gate array (PGA) or a field programmable gate array (FPGA) with a suitable combinational logic.

The flowchart and block diagrams in the flow diagrams illustrate the architecture, functionality, and operation of possible implementations of systems, methods, and computer program products according to various embodiments of the present embodiments. In this regard, each block in the flowchart or block diagrams may represent a module, segment, or portion of code, which comprises one or more executable instructions for implementing the specified logical function(s). It is also noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions. These computer program instructions can be stored in a computer-readable medium that directs a computer or other programmable data processing apparatus to function in a particular manner, such that the instructions stored in the computer-readable medium produce an article of manufacture including instruction means which implement the function/act specified in the flowchart and/or block diagram block or blocks.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of building a characteristic model, comprising:
acquiring raw electrical data from a measurement system outside one or more processing units;
acquiring operational state-related data from an information collector inside the one or more processing units;
performing a data annealing process on the raw electrical data and the operational state-related data to obtain the purified electrical data and purified operational state-related data; and
performing a machine learning (ML)-based process to build the characteristic model based on the purified electrical data and the purified operational state-related data.

2. The method of claim 1, further comprising:
performing a synchronization process to align the raw electrical data with the operational state-related data in time; and
performing the data annealing process on the raw electrical data and the operational state-related data that are aligned in time to obtain the purified electrical data and the purified operational state-related data.

3. The method of claim 2, wherein the step of performing the synchronization process to align the raw electrical data with the operational state-related data in time comprises:
obtaining a plurality of first samples by sampling measurement of electrical data including at least one of power, current, voltage, and impedance outputted by a power source at a first sampling rate during a synchronization period;
obtaining a second sample by sampling internal information from the information collector at a second sampling rate during the synchronization period, wherein the second sampling rate is lower than the first sampling rate; and
serving filters of the first samples as the raw electrical data; and
serving the second sample as the operational state-related data.

4. The method of claim 1, wherein the step of performing the data annealing process on the raw electrical data to obtain the purified electrical data comprising:
calculating the purified electrical data according to the raw electrical data, a conversion efficiency of power conversion devices that supply electrical power to the one or more processing units, and leakage power of the one or more processing units.

5. The method of claim 1, wherein the step of performing the data annealing process on the operational state-related data to obtain the purified operational state-related data comprising:
performing a ML algorithm to select a plurality of essential features from the operational state-related data.

6. The method of claim 5, wherein the step of performing the ML algorithm to select the plurality of essential features from the operational state-related data comprises:
selecting a plurality of features from a plurality of attributes of the one or more processing unit that are included in the operational state-related data according to a Pearson correlation coefficient corresponding to each of the attributes of the one or more processing units.

7. The method of claim 6, wherein the step of performing the ML algorithm to select the plurality of essential features from the operational state-related data comprises:
selecting a plurality of first selected features from the plurality of features, wherein each of the first selected features has correlation and/or interaction factors lower than a predetermined threshold; and
selecting the plurality of essential selected features from the first selected features, wherein coefficients of determination that the essential selected features correspond to are higher than coefficients of determination that others in the first selected features correspond to, and residual sums of squares that the essential features correspond to are smaller than residual sums of squares that others in the first selected features correspond to.

8. The method of claim 1, further comprising:
utilizing the information collector to collect internal information from at least one of sensor data that is provided by one or more sensors, status data that is provided by one or more tracers and performance monitoring unit (PMU) data that is provided by one or more PMU Counters, wherein the one or more sensors, the one or more tracers and the one or more PMU Counters are included in each of the one or more processing units; and
acquiring the operational state-related data from the internal information.

9. The method of claim 1, wherein the step of performing the ML-based process to build the characteristic model comprises:
utilizing a machine-learning method to train the characteristic model according to a plurality of data sets including the purified electrical data and the purified operational state-related data.

10. The method of claim 1, further comprising:
generating a capacitance estimation model according to the built characteristic model;
generating an admittance/impedance estimation model according to the built characteristic model;
generating a current estimation model according to the built characteristic model; or
generating a power estimation model according to the built characteristic model.

11. The method of claim 1, further comprising:
acquiring raw electrical data of one or more associated system units interconnected to the one or more processing units from the measurement system;
acquiring operational state-related data of the one or more associated system from an information collector inside the one or more associated system units;
performing the data annealing process on the raw electrical data of the one or more associated system and the operational state-related of the one or more associated system data to obtain the purified electrical data and purified operational state-related data of the one or more associated system; and
performing the ML-based process to build the characteristic model based on the purified electrical data and the purified operational state-related data of the one or more associated system.

12. A modeling system of building a characteristic model, comprising:
a data annealing process, configured to purify raw electrical data from a measurement system outside one or more processing units and operational state-related data from an information collector inside the one or more processing units, thereby to obtain purified electrical data and purified operational state-related data; and
a machine learning (ML)-based process, configured to build the characteristic model based on the purified electrical data and the purified operational state-related data.

13. The modeling system of claim 12, further comprising:
a synchronization process, configured to align the raw electrical data with the operational stat related data in time, wherein the data annealing process is configured to purify the raw electrical data and the operational state-related data that are aligned in time to obtain the purified electrical data and the purified operational state-related data.

14. The modeling system of claim 13, wherein the synchronization process is configured to:
obtain a plurality of first samples by sampling measurement of electrical data including at least one of power, current, voltage, and impedance outputted by a power source at a first sampling rate during a synchronization period;
obtain a second sample by sampling internal information from the information collector at a second sampling rate during the synchronization period, wherein the second sampling rate is lower than the first sampling rate; and
serve filters of the first samples as the raw electrical data; and
serve the second sample as the operational state-related data.

15. The modeling system of claim 12, wherein the data annealing process comprises:
a purification process, configured to calculate the purified electrical data according to the raw electrical data, a conversion efficiency of power conversion devices that supply electrical power to the one or more processing units, and leakage power of the one or more processing units.

16. The modeling system of claim 12, wherein the data annealing process is configured to execute a ML algorithm to select a plurality of essential features from the operational state-related data.

17. The modeling system of claim 16, wherein the data annealing process is configured to select a plurality of features from a plurality of attributes of the one or more processing unit that are included in the operational state-related data according to a Pearson correlation coefficient corresponding to each of the attributes of the one or more processing units.

18. The modeling system of claim 17, wherein the data annealing process is configured:
select a plurality of first selected features from the plurality of features, wherein each of the first selected features has correlation factors lower than a predetermined threshold; and
select the plurality of essential features from the first selected features, wherein coefficients of determination that the essential features correspond to are higher than coefficients of determination that others in the first selected features correspond to, and residual sums of squares that the essential correspond to are smaller than residual sums of squares that others in the first selected features correspond to.

19. The modeling system of claim 12, wherein the operational state-related data are acquired from internal information that is collected by the information collector from at least one of sensor data that is provided by one or more sensors, status data that is provided by one or more tracers and performing monitor unit (PMU) data that is provided by one or more PMUs, wherein the one or more sensors, the one or more tracers and the one or more PMUs are included in each of the one or more processing units.

20. The modeling system of claim 12, wherein the ML-based process is configured to utilize regression methods to train the characteristic model according to a plurality of data sets including the purified electrical data and the purified operational state-related data.

21. The modeling system of claim 12, the ML-based process is configured to:
generate a capacitance estimation model according to the built characteristic model;
generate a admittance/impedance estimation model according to the built characteristic model;
generate a current model according to the built characteristic model; or
generate an power estimation model according to the built characteristic model.

22. The modeling system of claim 12, wherein the data annealing process is further configured to purify raw electrical data of one or more associated system units interconnected to the one or more processing units from the measurement system and operational state-related data of the one or more associated system from an information collector inside the one or more associated system units, thereby to obtain purified electrical data and purified operational state-related data of the one or more associated system units; and the ML-based process is further configured to build the characteristic model based on the purified electrical data and the purified operational state-related data of the one or more associated system.
